(19) United States
(12) Patent Application Publication
(10) Pub. No.: US 2020/0035717 A1
(43) Pub. Date: Jan. 30, 2020

(54) THIN FILM TRANSISTOR SUBSTRATE AND METHOD OF PRODUCING THIN FILM TRANSISTOR SUBSTRATE

(71) Applicant: Sharp Kabushiki Kaisha, Sakai City (JP)

(72) Inventors: Kengo HARA, Sakai City (JP); Tohru DAITOH, Sakai City (JP); Hajime IMAI, Sakai City (JP); Tetsuo KIKUCHI, Sakai City (JP); Masahiko SUZUKI, Sakai City (JP); Setsuji NISHIMIYA, Sakai City (JP); Teruyuki UEDA, Sakai City (JP); Masamitsu YAMANAKA, Sakai City (JP)

(21) Appl. No.: 16/508,603

(22) Filed: Jul. 11, 2019

Related U.S. Application Data
(60) Provisional application No. 62/703,453, filed on Jul. 26, 2018.

(51) Int. Cl. H01L 27/12; H01L 29/786

(52) U.S. Cl. CPC H01L 27/1225; H01L 29/7869; H01L 27/127; H01L 27/124

(57) ABSTRACT

A thin film transistor substrate includes a source line, a gate electrode, a channel region, a source region, a drain region, and a pixel electrode. The gate electrode is a portion of a first metal film disposed upper than a first insulating film that is disposed upper than a semiconductor film. The source line is a portion of a second metal film disposed upper than a second insulating film that is disposed upper than the first metal film. The channel region is a portion of a section of the semiconductor film and disposed to overlap the gate electrode. The source region is prepared by reducing a resistance of a section of the semiconductor film. The drain region is prepared by reducing a resistance of a section of the semiconductor film. The pixel electrode is prepared by reducing a resistance of a section of the semiconductor film.

### CROSS REFERENCE TO RELATED APPLICATION

This application claims priority from U.S. Provisional Patent Application No. 62/703,453 filed on Jul. 26, 2018. The entire contents of the priority application are incorporated herein by reference.

### TECHNICAL FIELD

The technology described herein relates to a thin film transistor substrate and the method of producing the thin film transistor substrate.

### BACKGROUND ART

A thin film transistor substrate included in a liquid crystal display device disclosed in Japanese Unexamined Patent Application Publication No. 2008-175842 has been known as an example. The thin film transistor substrate includes a transparent oxide layer, an insulating film, and a conductive layer disposed on to of each other in sequence in a pixel region on a substrate. The conductive layer includes gate electrodes of thin film transistors connected to gate signal lines. The transparent oxide layer includes regions at least other than channel regions immediately below the gate electrodes. The regions are configured as electric conductors. Source lines, source regions of the thin film transistors connected to the source lines, pixel electrodes, and drain regions of the thin film transistors connected to the pixel electrodes are includes in the regions that configured as the electric conductors.

The source signal lines in the thin film transistor substrate disclosed in Patent Document 1 are formed by etching a metal film directly formed on the transparent oxide layer. According to the configuration, if pieces of the metal film on the transparent oxide layer are not removed by the etching, the remaining pieces may cause defects such as short circuits between the pixel electrodes and the source signal lines. Furthermore, the transparent oxide layer may be over-etched during the etching of the metal film on the transparent oxide layer.

### SUMMARY

The technology described herein was made in view of the above circumstances. An object is to reduce defects that may be caused by etching of a second metal film.

A thin film transistor substrate according to the technology described herein includes a semiconductor film, a first insulating film, a first metal film, a second insulating film, a second metal film, a source line, a gate electrode, a channel region, a source region, a drain region, and a pixel electrode. The first insulating film is disposed in a layer upper than the semiconductor film. The first metal film is disposed in a layer upper than the first insulating film. The second insulating film is disposed in a layer upper than the first metal film. The second metal film is disposed in a layer upper than the second insulating film. The source line is a portion of the second metal film. The gate electrode is a portion of the first metal film and included in the thin film transistor. The channel region is a portion of a section of the semiconductor film, disposed to overlap the gate electrode, and included in the thin film transistor. The source region is prepared by reducing a resistance of a section of the semiconductor film, coupled to the channel region, connected to the source line via a contact hole formed in the second insulating film, and included in the thin film transistor. The drain region is prepared by reducing a resistance of a section of the semiconductor film, coupled to the channel region on an opposite side from the source region, and included in the thin film transistor. The pixel electrode is prepared by reducing a resistance of a section of the semiconductor film and coupled to the drain region.

A method of producing a thin film transistor substrate according to the technology described herein includes a semiconductor film forming step, a first insulating film forming step, a first metal film forming step, a first metal film etching step, a semiconductor film etching step, a resistance reducing step, a second insulating film forming step, a second insulating film etching step, a second metal film forming step, and a second metal film etching step. The semiconductor film forming step is for forming a semiconductor film. The first insulating film forming step is for forming a first insulating film in a layer upper than the semiconductor film. The first metal film forming step is for forming a first metal film in a layer upper than the first insulating film. The first metal film etching step is for etching the first metal film and the first insulating film together to prepare a gate electrode from the first metal film. The gate electrode is included in a thin film transistor. The semiconductor film etching step is for etching the semiconductor film. The resistance reducing step is for reducing resistances of sections of the semiconductor film other than a channel region overlapping the gate electrode to prepare a source region to be coupled to the channel region and included in the thin film transistor, a drain region to be coupled to the channel region on an opposite side from the source region and included in the thin film transistor, and a pixel electrode to be coupled to the drain region. The second insulating film forming step is for forming a second insulating film in a layer upper than the first metal film. The second insulating film etching step is for etching the second insulating film to form a contact hole in a section overlapping a section of the source region. The second metal film forming step is forming a second metal film in a layer upper than the second insulating film. The second metal film etching step is for etching the second metal film to prepare a source line to be connected to the source region via the contact hole.

The semiconductor film, the first insulating film, and the first metal film are formed through the semiconductor film forming step, the first insulating film forming step, and the first metal film forming step. In the first metal film etching step, the first metal film is etched together with the first insulating film. In the semiconductor film etching step, the semiconductor film is etched. In the resistance reducing step, the resistances of the sections of the semiconductor film other than the channel region are reduced. As a result, the source region, the drain region, and the pixel electrode are prepared. In comparison to a method including preparing a pixel electrode from a transparent electrode film, forming and etching of the transparent electrode film are not required. Furthermore, an insulating film for isolating the transparent electrode film from another conductor film is not required. This method is preferable for reducing a production cost. The contact hole is formed in the section of the second insulating film overlapping the section of the source region by etching the second insulating film formed in the second insulating film forming step in the second insulating film etching step. The second metal film formed in the layer upper than the second insulating film in the second metal film forming step is etched in the second metal film etching step and the source line to be connected to the source region via the contact hole is prepared. In the second metal film etching step, at least a section of the semiconductor film is covered with the second insulating film. Even if the second metal film is not properly etched and film residues are present, a defect such as a short-circuit between the source line and the section of the semiconductor film having the reduced resistance is less likely to occur due to the film residues. Because at least the section of the semiconductor film is covered with the second insulating film, the semiconductor film is less likely to be over-etched in the second metal film etching step.

According to the technology described herein, defects that may be caused by etching of the second metal film can be reduced.

### BRIEF DESCRIPTION OF THE DRAWINGS

FIG. 1 is a plan view schematically illustrating a two-dimensional configuration of an array substrate in a display area included in a liquid crystal panel according to a first embodiment.

FIG. 2 is a cross-sectional view of the array substrate along line A-A in FIG. 1.

FIG. 3 is a cross-sectional view of the array substrate along line A-A in FIG. 1 after a lower metal film forming step and a lower metal film etching step included in a method of producing the array substrate.

FIG. 4 is a cross-sectional view of the array substrate along line A-A in FIG. 1 after a lower insulating film forming step, a semiconductor film forming step, a first insulating film forming step, a first metal film forming step, a first metal film etching step included in the method of producing the array substrate.

FIG. 5 is a cross-sectional view of the array substrate along line A-A in FIG. 1 after a semiconductor film etching step included in the method of producing the array substrate.

FIG. 6 is a cross-sectional view of the array substrate along line A-A in FIG. 1 after a resistance reducing step included in the method of producing the array substrate.

FIG. 7 is a cross-sectional view of the array substrate along line A-A in FIG. 1 after a second insulating film forming step and a second insulating film etching step included in the method of producing the array substrate.

FIG. 8 is a cross-sectional view of the array substrate along line A-A in FIG. 1 after a second metal film forming step and a second metal film etching step included in the method of producing the array substrate.

FIG. 9 is a plan view schematically illustrating a two-dimensional configuration of an array substrate in a display area included in a liquid crystal panel according to a second embodiment.

FIG. 10 is a cross-sectional view of the array substrate along line B-B in FIG. 9.

FIG. 11 is a cross-sectional view of the array substrate along line C-C in FIG. 9.

FIG. 12 is a cross-sectional view of a TFT in an array substrate according to a third embodiment.

FIG. 13 is a cross-sectional view of the TFT in the array substrate after a resistance reducing step included in a method of producing the array substrate.

FIG. 14 is a cross-sectional view of the TFT in the array substrate after a second insulating film forming step and a second insulating film etching step included in a method of producing the array substrate.

FIG. 15 is a plan view schematically illustrating a two-dimensional configuration of an array substrate in a display area included in a liquid crystal panel according to a fourth embodiment.

FIG. 16 is a cross-sectional view of the array substrate line D-D in FIG. 15.

FIG. 17 is a plan view schematically illustrating a two-dimensional configuration of an array substrate in a display area included in a liquid crystal panel according to a fifth embodiment.

FIG. 18 is a cross-sectional view of the array substrate line E-E in FIG. 17.

### DETAILED DESCRIPTION

### First Embodiment

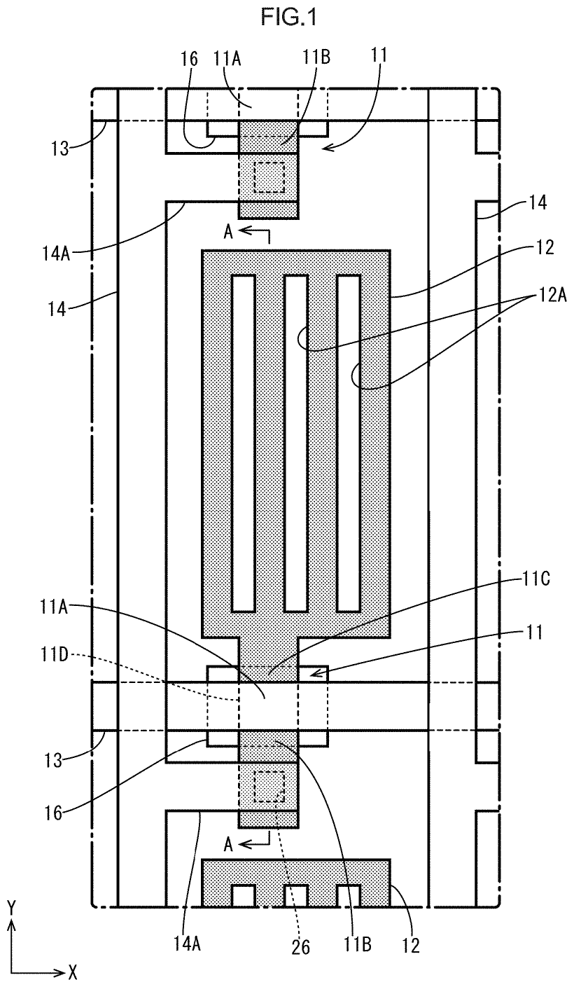

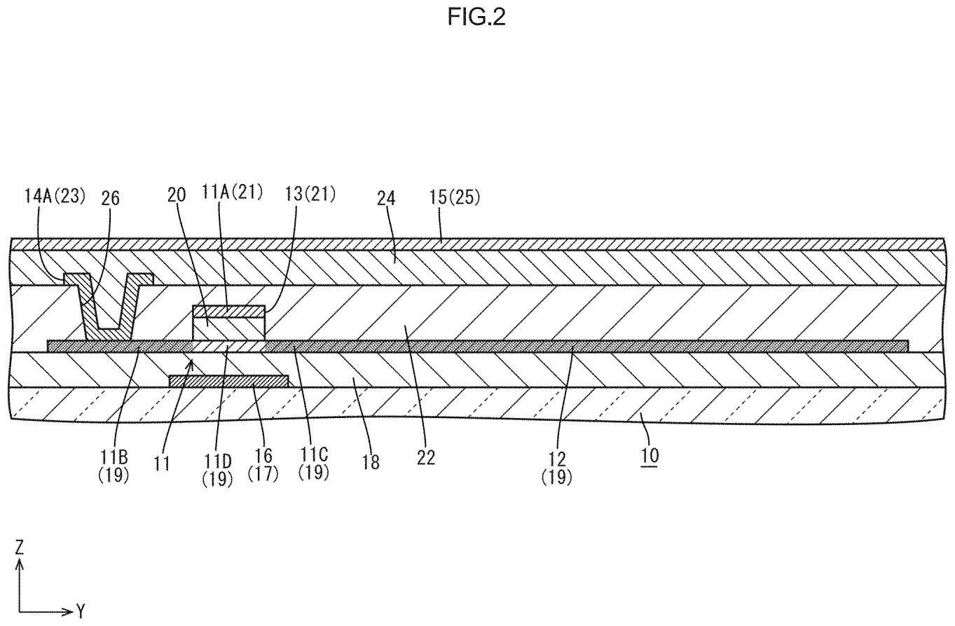

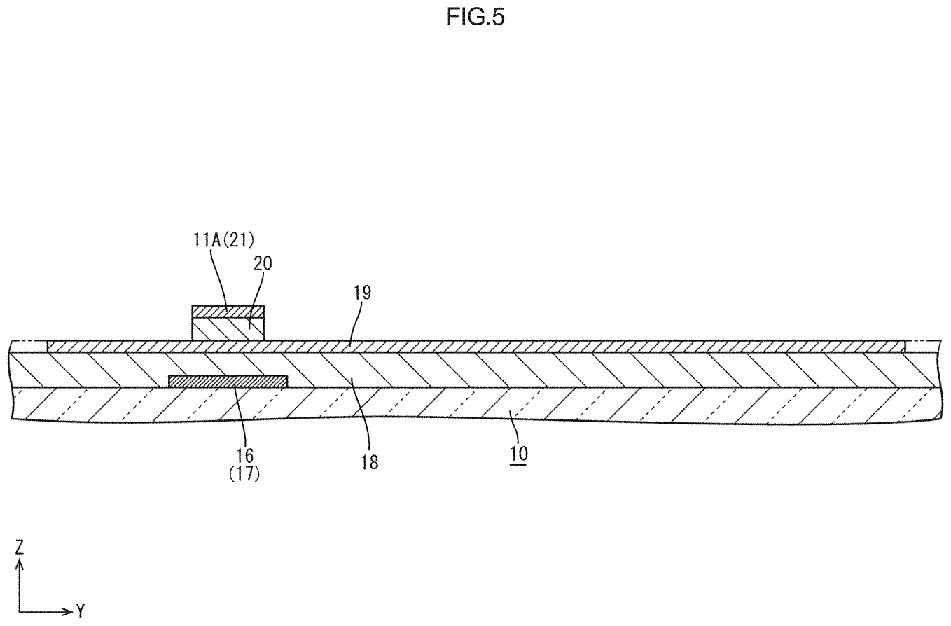

A first embodiment will be described with reference to FIGS. 1 to 8. In this section, an array substrate 10 (a thin film transistor substrate) included in a liquid crystal panel (a display panel) will be described. X-axes, Y-axes, and Z-axes may be present in the drawings. The axes in each drawing correspond to the respective axes in other drawings. An upper side and a lower side in FIGS. 2 to 8 correspond to a front side and a backside of the liquid crystal panel, respectively.

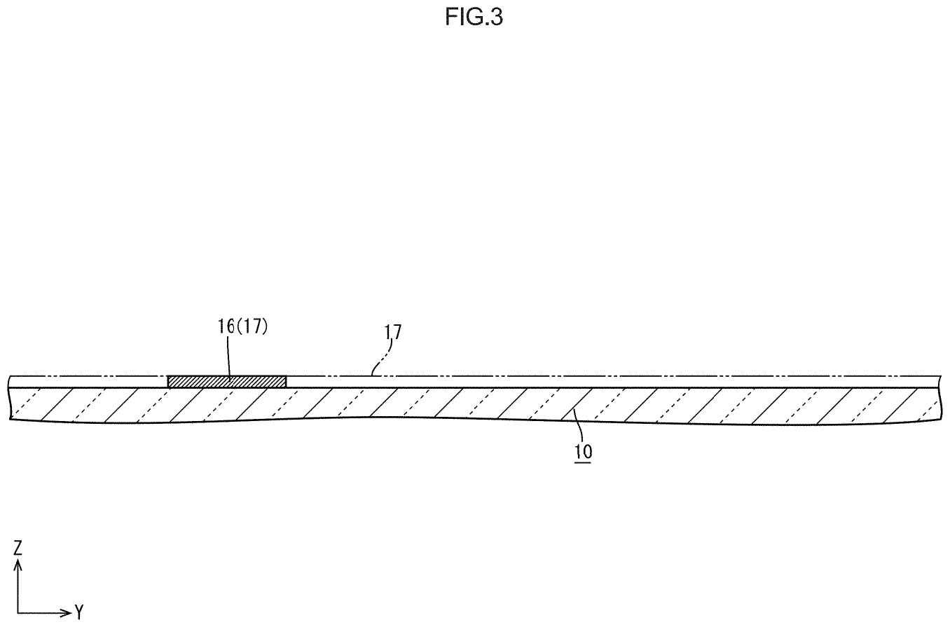

The liquid crystal panel includes the array substrate 10 and a CF substrate (a common substrate) bonded together with a liquid crystal layer therebetween. Polarizing plates are bonded to outer surfaces of the array substrate 10 and the CF substrate. The liquid crystal panel includes a display surface that is sectioned into a display area in which images are displayed and a non-display area that surrounds the display area. FIG. 1 is a plan view of the display area of the array substrate 10. As illustrated in FIG. 1, thin film transistors (TFTs) 11 and pixel electrodes 12 are disposed in a matrix in the display area of the array substrate 10. The TFTs 11 are switching components. Gate lines 13 (scanning lines) and source lines 14 (data lines, signal lines) are routed in a grid to surround the TFTs 11 and the pixel electrodes 12. The gate lines 13 and the source lines 14 are connected to gate electrodes 11A and source regions 11B of the TFTs 11, respectively. The pixel electrodes 12 are connected to drain regions 11C of the TFTs 11. The TFTs 11 are driven based on various signals through the gate lines 13 and the source lines 14. Application of potentials to the pixel electrodes 12 is controlled based on the driving of the TFTs 11. The pixel electrodes 12 are disposed in vertically long rectangular areas surrounded by the gate lines 13 and the source lines 14. Each pixel electrode 12 includes slits 12A (three slits in FIG. 3) which extend along a longitudinal direction thereof (the Y-axis direction). In the display area of the array substrate 10, a common electrode 15 is formed in a substantially solid pattern to overlap the pixel electrodes 12. When a potential difference is created between the pixel electrode 12 and the common electrode 15 that overlap each other, a fringe electric field (an oblique electric field) including a component in a normal direction to a plate surface of the array substrate 10 in addition to a component along the plate surface of the array substrate 10 is applied to a portion of the liquid crystal layer around the slits 12A. Namely, the liquid crystal panel including the array substrate 10 according to this embodiment is configured to operate in fringe field switching (FFS) mode. In this embodiment, an extending direction in which the gate lines 13 extend corresponds to the X-axis direction and an extending direction in which the source lines 14 extend corresponds to the Y-axis direction in the drawings.

More specifically, as illustrated in FIG. 1, the TFTs 11 are adjacent to lower sides of the respective pixel electrodes 12 to which the TFTs 11 are connected in the Y-axis direction in FIG. 1. The TFTs 11 include gate electrodes 11A that are sections of the gate lines 13. The TFTs 11 include the source regions 11B connected to source branch lines 14A that branch off from the source lines 14. The source branch lines 14A are disposed on an opposite side from the pixel electrodes 12 to which the source branch lines 14A connected with respect to intersections between the source lines 14 and the gate lines 13. The source branch lines 14A extend in the X-axis direction. Distal ends of the source branch lines 14A are connected to the source regions 11B. Image signals transmitting through the source lines 14 are supplied to the source regions 11B via the source branch lines 14A. The source regions 11B extend in the Y-axis direction. The TFTs 11 include the drain regions 11C separated from the source regions 11B in the Y-axis direction. The drain regions 11C extend in the Y-axis direction. Ends of the drain regions 11C on an opposite side from the source regions 11B (channel regions 11D) are coupled to the pixel electrodes 12. The TFTs 11 include the channel regions 11D that overlap the gate electrodes 11A and coupled to the source regions 11B and the drain regions 11C. The channel regions 11D extend in the Y-axis direction. First ends of the channel regions 11D are coupled to the source regions 11B and second ends of the channel regions 11D are coupled to the drain regions 11C. When the TFTs 11 are driven based on the scanning signals supplied to the gate electrodes 11A, the image signals (electric charges) supplied to the source lines 14 are supplied from the source branch lines 14A and the source regions 11B to the drain regions 11C via the channel regions 11D. As a result, the pixel electrodes 12 are charged with the potentials based on the image signals. The array substrate 10 includes a light blocking portion 16 to overlap at least the channel regions 11D in the display area. The light blocking portion 16 is capable of blocking light applied to the channel regions 11D from the lower layer. The light may be applied to the liquid crystal panel by the backlight unit for image display. Because the light toward the channel regions 11D is blocked by the light blocking portion 16, variations in characteristics of the TFTs 11, which may be caused by the light applied to the channel regions 11D, can be reduced.

In a display area of the CF substrate, color filters are disposed in a matrix to be opposed to the pixel electrodes 12 in the array substrate 10. The color filters include red (R), green (G), and blue (B) color portions in a predefined sequence. A light blocking film (a black matrix) is formed among the color filters for reducing color mixture.

FIG. 2 is a cross-sectional view of the array substrate 10 along line A-A in FIG. 1. As illustrated in FIG. 2, the array substrate 10 includes a glass substrate (a substrate) and various films disposed on top of each other on an inner surface of the glass substrate. Specifically, as illustrated in FIG. 2, the array substrate 10 includes a lower metal film 17, a lower insulating film 18, a semiconductor film 19, a first insulating film 20, a first metal film 21 (a gate metal film), a second insulating film 22, a second metal film (a source metal film), a third insulating film 24, a transparent electrode film 25, an alignment film disposed in this sequence from a lower side (a glass substrate side, a side away from the liquid crystal layer).

Each of the lower metal film 17, the first metal film 21, and the second metal film 23 includes a single-layer film made of one kind of metal material, a multi-layer film made of different kinds of metal material, or an alloy to have conductivity and light blocking properties. As illustrated in FIG. 2, the light blocking portion 16 is a portion of the lower metal film 17. The gate lines 13, the gate electrodes 11A of the TFTs 11 are portions of the first metal film 21. The source lines 14 (including the source branch lines 14A) are portions of the second metal film 23. The lower insulating film 18 and the third insulating film 24 are made of silicon nitride (SiNₓ), which is a kind of inorganic insulating material (inorganic resin material). The first insulating film 20 and the second insulating film 22 are made of oxide silicon or silicon oxide (SiO₂), which is a kind of inorganic insulating material. The lower insulating film 18 is disposed between the lower metal film 17 and the semiconductor film 19 to isolate them from each other. The first insulating film 20 is disposed between the semiconductor film 19 and the first metal film 21 to isolate them from each other. Distances between the gate electrodes 11A and the channel regions 11D are maintained constant with sections of the first insulating film 20 overlapping the gate electrodes 11A. The second insulating film 22 is disposed between the first metal film 21 and the second metal film 23 to isolate them from each other. The third insulating film 24 is disposed between the second metal film 23 and the transparent electrode film 25 to isolate them from each other. The semiconductor film 19 is an oxide semiconductor film made of an oxide semiconductor material. The source regions 11B, the drain regions 11C, the channel regions 11D of the TFTs 11 and the pixel electrodes 12 are portions of the semiconductor film 19. Examples of material of the semiconductor film 19 include an indium-gallium-zinc-oxide (In—Ga—Zn—O) based semiconductor. The In—Ga—Zn—O based semiconductor is a ternary oxide including indium (In), gallium (Ga), and zinc (Zn). Percentages (ratios) of the In, Ga, and Zn are not limited to specific numbers. For example, but not limited to, In:Ga:Zn=2:2:1, 1:1:1, or 1:1:2. The n-Ga—Zn—O based semiconductor may be an amorphous semiconductor or a crystalline semiconductor. The crystalline semiconductor may be a crystalline In—Ga—Zn—O based semiconductor having a C-axis substantially perpendicular to a layer surface. The transparent electrode film 25 is made of a transparent electrode material such as indium tin oxide (ITO) and indium zinc oxide (IZO). The common electrode 15 is a portion of the transparent electrode film 25. The alignment film is for initial alignment of liquid crystal molecules in the liquid crystal layer. The TFTs 11 in this embodiment are so-called top gate-type in which the gate electrodes 11A are portions of the first metal film 21 disposed over the channel regions 11D that are portions of the semiconductor film 19 via the first insulating film 20.

The source regions 11B, the drain regions 11C, and the pixel electrodes 12 included in the array substrate 10 in this embodiment are prepared by reducing resistances of sections of the semiconductor film 19 in a production process as illustrated in FIG. 2. The source regions 11B, the drain regions 11C, and the pixel electrodes 12 (resistance-reduced regions of the semiconductor film 19) have resistivity that is about 1/10000000000 to 1/100 of resistivity of resistance non-reduced regions (the channel regions 11D) of the semiconductor film 19. Namely, the resistivity is significantly small and thus the source regions 11B, the drain regions 11C, and the pixel electrodes 12 function as conductors. The semiconductor film 19 including the resistance-reduced regions is made of substantially transparent light transmissive material. Therefore, the pixel electrodes 12 have sufficient levels of transparency and light transmissivity. The charges can be transferred in the resistance non-reduced regions of the semiconductor film 19 under specific conditions (when the scan signals are supplied to the gate electrodes 11A). The charges can be always transferred in the resistance-reduced regions, that is, the resistance-reduced regions function as conductors. As described above, the source regions 11B, the drain regions 11C, and the pixel electrodes 12 in this embodiment are prepared by reducing the resistances of the sections of the semiconductor film 19. Therefore, forming and etching of the transparent electrode film are not required. Furthermore, insulating films for isolating the transparent electrode film from other conductive films are not required. In comparison to pixel electrodes prepared from a transparent electrode film, this configuration is more preferable for reducing the production cost. In FIGS. 1 and 2, the resistance-reduced regions of the semiconductor film are shaded.

The source regions 11B of the TFTs 11 in this embodiment, which are the portions of the semiconductor film 19, and the source branch lines 14A of the source lines 14, which are the portions of the second metal film 23, are connected to each other via contact holes 26 in the second insulating film 22 disposed therebetween as illustrated in FIG. 2. According to the configuration, at least sections of the semiconductor film 19 are covered with the second insulating film 22 when the source lines 14 (including the source branch lines 14A) are formed by etching the second metal film 23 formed in the layer upper than the second insulating film 22 in the production process. Even if the etching of the second metal film 23 is not properly performed and film residues are present, short circuit between the source lines 14 and the resistance-reduced regions of the semiconductor film 19 due to the film residues are less likely to occur. Because at least sections of the semiconductor film 19 are covered with the second insulating film 22, the semiconductor film 19 is less likely to be over-etched during the etching of the second metal film 23.

As illustrated in FIG. 2, the gate electrodes 11A and the gate lines 13 of the TFTs 11 are portions of the first metal film 21. Therefore, the signals transmitting through the gate lines 13 are directly supplied to the gate electrodes 11A. If the gate lines are prepared from the lower metal film 17 disposed in a layer lower than the first metal film 21, contact holes need to be formed in the lower insulating film 18. In comparison to such a configuration, structures for connecting the gate lines 13 to the gate electrodes 11A prepared from the first metal film 21 can be simplified. Furthermore, the first insulating film 20 is disposed in an area overlapping the gate electrodes 11A and the gate lines 13. Therefore, the first insulating film 20 can be etched together with the first metal film 21 that is etched after the first insulating film 20 and the first metal film 21 are formed in sequence in the production process. Because a photomask is not required for patterning the first insulating film 20, the production cost can be reduced.

As illustrated in FIG. 2, the second insulating film 22 is disposed to cover at least the drain regions 11C and the pixel electrodes 12. Therefore, at least the drain regions 11C and the pixel electrodes 12 are covered with the second insulating film 22 during the etching of the second metal film 23 formed in the layer upper than the second insulating film 22 to form the source lines in the production process. Even if the second metal film 23 is not properly etched and film residues are present, defects such as short-circuits between the source lines 14 and at least one of the drain regions 11C and the pixel electrodes 12 due to the film residues are less likely to occur. With at least the drain regions 11C and the pixel electrodes 12 covered with the second insulating film 22, at least the drain regions 11C and the pixel electrodes 12 are less likely to be over-etched during the etching of the second metal film 23. The second insulating film 22 covers sections of the source regions 11B not overlapping the contact holes 26 (including sections adjacent to the channel regions 11D) other than the drain regions 11C and the pixel electrodes 12.

The array substrate 10 in this embodiment has the configuration described above. Next, a method of producing the array substrate 10 will be described. The method of producing the array substrate 10 according to this embodiment includes at least a lower metal film forming step, a lower metal film etching step, a lower insulating film forming step, a semiconductor film forming step, a first insulating film forming step, a first metal film forming step, a first metal film etching step, a semiconductor film etching step, a resistance reducing step, a second insulating film forming step, a second insulating film etching step, a second metal film forming step, a second metal film etching step, a third insulating film forming step, a transparent electrode forming step, and an alignment film forming step. The lower metal film forming process is for forming the lower metal film 17. The lower metal film etching step is for etching the lower metal film 17. The lower insulating film forming step is for forming the lower insulating film 18. The semiconductor film forming step is for forming the semiconductor film 19. The first insulating film forming step is for forming the first insulating film 20. The first metal film forming step is for forming the first metal film 21. The first metal film etching step is for etching the first metal film 21 together with the first insulating film. The semiconductor film etching step is for etching the semiconductor film 19. The resistance reducing step is for reducing the sections of the semiconductor film 19. The second insulating film forming step is for forming the second insulating film 22. The second insulating film etching step is for etching the second insulating film 22. The second metal film forming step is for forming the second metal film 23. The second metal film etching step is for etching the second metal film 23. The third insulating film forming step is for forming the third insulating film 24. The transparent electrode film forming step is for forming the transparent electrode film 25. The alignment film forming step is for forming the alignment film. The steps will be described in detail with reference to FIGS. 3 to 8.

As illustrated in FIG. 3, in the lower metal film etching step, a photoresist is overlaid on the lower metal film formed in the lower metal film forming step and the photoresist is exposed and developed. Then, the lower metal film 17 is dry-etched or wet-etched using the photoresist obtained through patterning. Sections of the lower metal film 17 on which the photoresist is not overlaid are etched and removed. Sections of the lower metal film 17 on which the photoresist is overlaid remain. As a result, the light blocking portion 16 is prepared from the lower metal film 17.

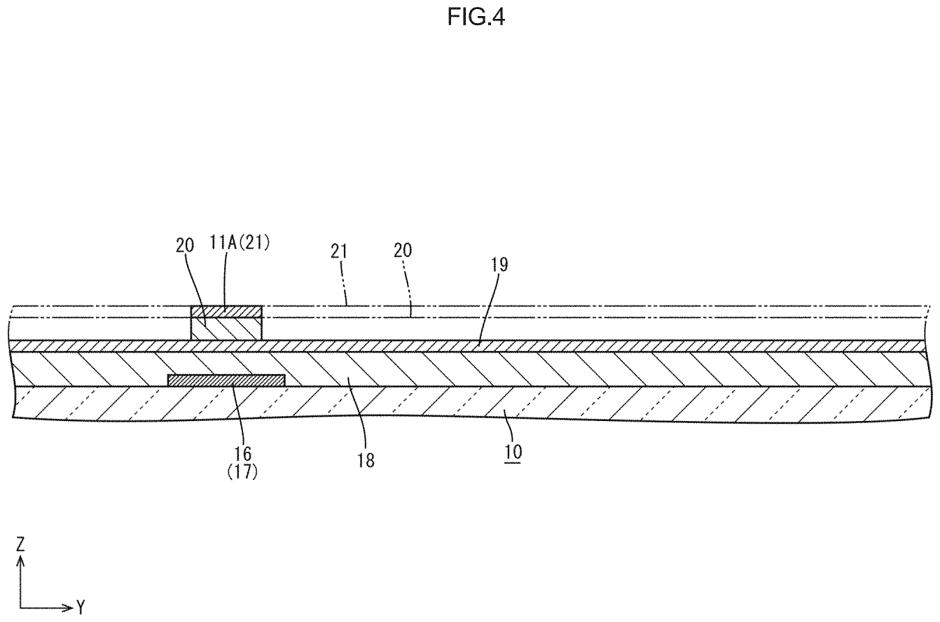

As illustrated in FIG. 4, the semiconductor film forming step, the first insulating film forming step, and the first metal film forming step are consecutively performed. Therefore, the semiconductor film 19, the first insulating film 20, and the first metal film 21 are consecutively formed on top of each other. In the first metal film etching step, the first metal film 21 is patterned through etching using a photoresist overlaid on the first metal film 21 and patterned similar to the lower metal film etching step described above. Because the first metal film 21 and the first insulating film 20 are etched, the first insulating film 20 and the first metal film 21 are formed in the same pattern. Through the step, the gate electrodes 11A and the gate lines 13 are prepared from the first metal film 21. The first metal film etching step is performed prior to the semiconductor film etching step. When the first metal film 21 is etched together with the first insulating film 20 in the first metal film etching step, the semiconductor film 19 is not patterned and thus the lower insulating film 18 under the semiconductor film 19 is covered with the semiconductor film 19. Therefore, the lower insulating film 18 is less likely to be over-etched during the etching of the first metal film 21. In the semiconductor film etching step, the semiconductor film 19 is patterned through etching using a photoresist overlaid on the semiconductor film 19 and patterned similar to the lower metal film etching step. Through the step, the channel regions 11D, the source regions 11B, the drain regions 11C, and the pixel electrodes 12 before the resistance reduction are formed.

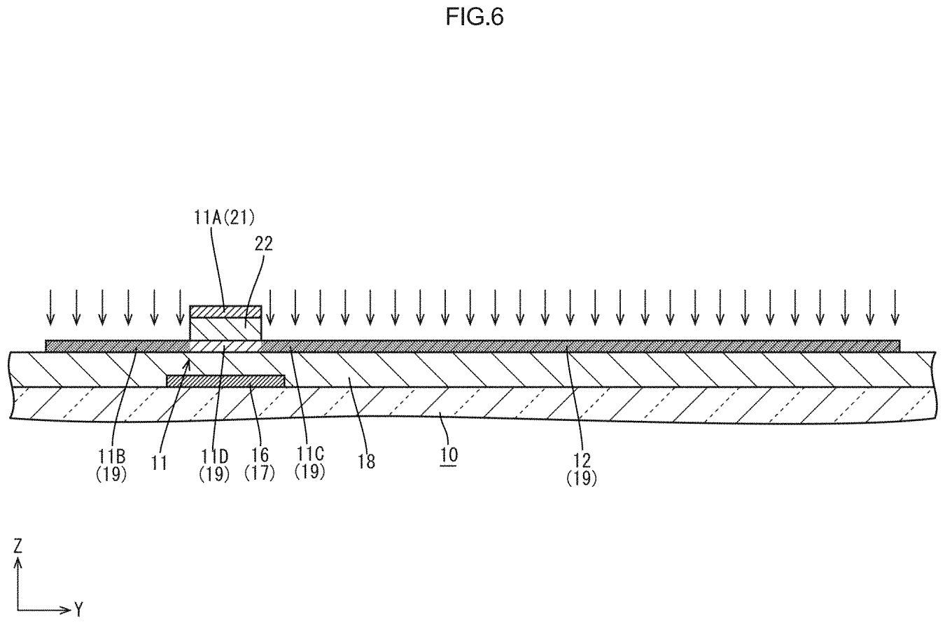

In the resistance reducing step, resistance of the semiconductor film 19 patterned in the semiconductor film etching step is reduced. The resistance may be reduced through plasma processing using predefined gas. As illustrated in FIG. 6, regions of the semiconductor film 19 other than regions that are covered with the gate electrodes 11A (the channel regions 11D) prepared from the first metal film 21 are exposed. The resistances of the exposed sections are reduced and the sections are defined as the resistance-reduced sections. Through the step, the source regions 11B, the drain regions 11C, and the pixel electrodes 12 are prepared from regions of the semiconductor film 19.

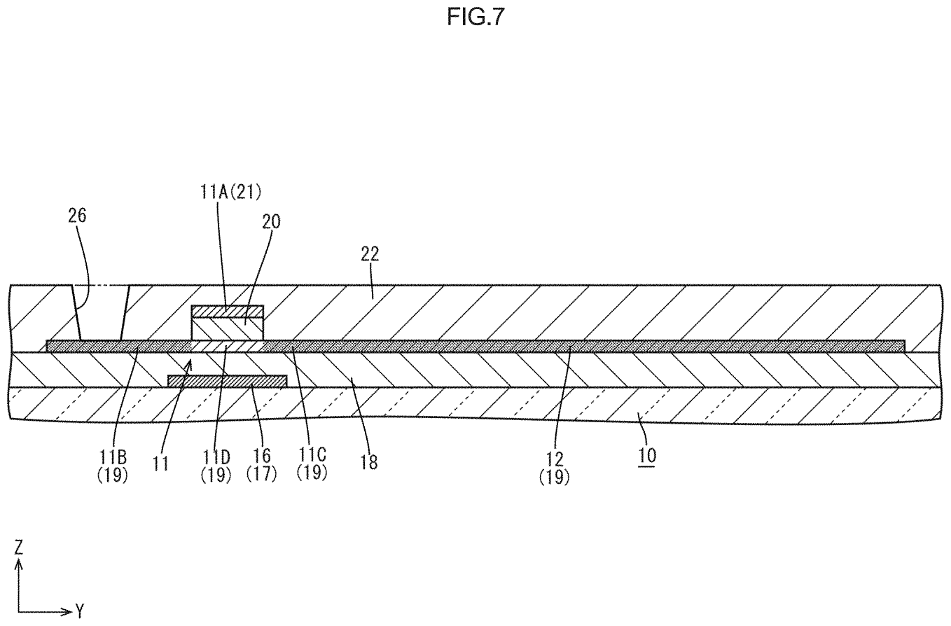

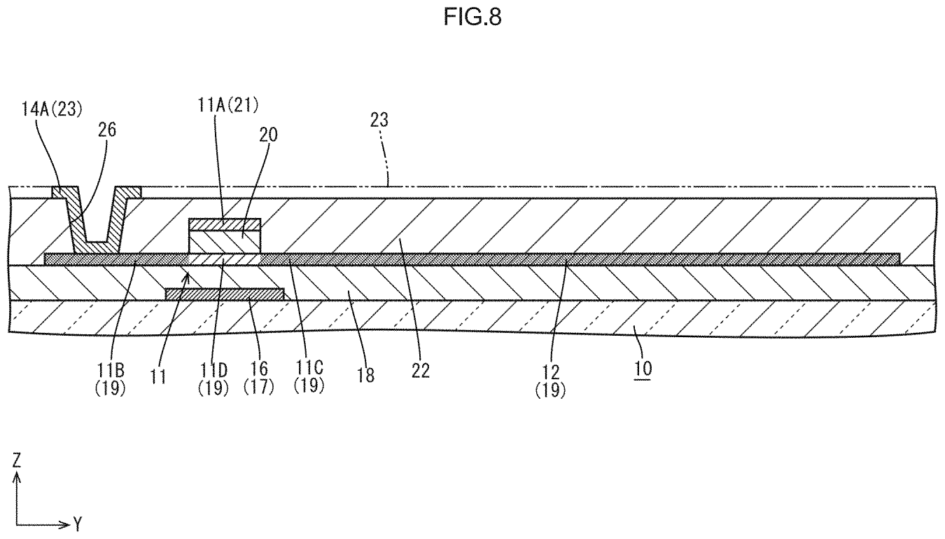

In the second insulating film etching step, as illustrated in FIG. 7, the second insulating film 22 is patterned through etching using a photoresist overlaid on the second insulating film 22 formed in the second insulating film forming step and patterned, similar to the lower metal film etching step described earlier. Through the step, the contact holes 26 are formed in the second insulating film 22 at positions overlapping sections of the source regions 11B. The sections of the source regions 11B overlapping the contact holes 26 are exposed. As illustrated in FIG. 8, in the second metal film forming step, the second metal film 23 is formed. A large section of the second metal film 23 that is formed is overlaid on the second insulating film 22. The sections overlapping the contact holes 26 are overlaid on the semiconductor film 19. In the second metal film etching step, the second metal film 23 is patterned through etching using a photoresist overlaid on the second metal film 23 and patterned, similar to the lower metal film etching step. Through the step, the source lines 14 and the source branch lines 14A are formed. The source branch lines 14A are connected to the source regions 11B via the contact holes 26. In the second metal film etching step, a large section of the semiconductor film 19 not overlapping the contact holes 26 (sections of the source regions 11B, the drain regions 11C, the channel regions 11D, and the pixel electrodes 12) is covered with the second insulating film 22. Even if the second metal film 23 is not properly etched and film residues are present, defects such as short-circuits between the source lines 14 and the drain regions 11C or the pixel electrodes 12 that are the regions of the semiconductor film 19 prepared by reducing the resistances are less likely to occur due to the film residues. Furthermore, the large section of the semiconductor film 19 is covered with the second insulating film 22 and thus the semiconductor film 19 is less likely to be over-etched in the second metal film etching step.

As illustrated in FIG. 2, the third insulating film 24 is formed in the third insulating film forming step, the transparent electrode film 25 is formed in the transparent electrode film forming step, and the alignment film is formed in the alignment film forming step.

As described earlier, the array substrate 10 (the thin film transistor substrate) in this embodiment includes the semiconductor film 19, the first insulating film 20 in the layer upper than the semiconductor film 19, the first metal film 21 in the layer upper than the first insulating film 20, the second insulating film 22 in the layer upper than the first metal film 21, and the second metal film 23 in the layer upper than the second insulating film 22. The array substrate 10 includes the source lines 14, the gate electrodes 11A, the channel regions 11D, the source regions 11B, the drain regions 11C, and the pixel electrodes 12. The source lines 14 are the portions of the second metal film 23. The gate electrodes 11A are the portions of the first metal film 21 and included in the TFTs (thin film transistors) 11. The channel regions 11D are the portions of sections of the semiconductor film 19 and included in the TFTs 11. The channel regions 11D are disposed to overlap the gate electrodes 11A. The source regions 11B are prepared by reducing the resistances of the sections of the semiconductor film 19 and included in the TFTs 11. The source regions 11B are coupled to the channel regions 11D and connected to the source lines 14 at least via the contact holes 26 in the second insulating film 22. The drain regions 11C are prepared by reducing the resistances of the sections of the semiconductor film 19 and included in the TFTs 11. The drain regions 11C are coupled to the channel regions 11D on an opposite side form the source regions 11B. The pixel electrodes 12 are prepared by reducing the resistances of the sections of the semiconductor film 19 and coupled to the drain regions 11C.

When voltages are applied to the gate electrodes 11A are the TFTs 11 are driven, the electric charges are transferred between the source regions 11B connected to the source lines 14 and the drain regions 11C via the channel regions 11D. As a result, the pixel electrodes 12 are charged. The source regions 11B, the drain regions 11C, and the pixel electrodes 12 are prepared by reducing the resistances of the sections of the semiconductor film 19. Therefore, forming and etching of the transparent electrode film are not required. Furthermore, insulating films for isolating the transparent electrode film from other conductive films are not required. In comparison to a configuration in which pixel electrodes are portions of a transparent electrode film, this configuration is preferable for reducing the production cost. The source lines 14 are the portions of the second metal film 23 disposed in the layer upper than the semiconductor film 19 via the second insulating film 22. Furthermore, the source lines 14 are connected to the source regions 11B that are prepared by reducing the resistances of the sections of the semiconductor film 19 via the contact holes 26 in the second insulating film 22. According to the configuration, at least the sections of the semiconductor film 19 are covered with the second insulating film 22 during the formation of the source lines by etching the second metal film 23 formed in the layer upper than the second insulating film 22 in the production process. Even if the etching of the second metal film 23 is not properly performed and film residues are present, defects such as short-circuits between the source lines 14 and the sections of the semiconductor film 19 prepared by reducing the resistances are less likely to occur due to the film residues. Furthermore, because at least the sections of the semiconductor film 19 are covered with the second insulating film 22, the semiconductor film 19 is less likely to be over-etched during the etching of the second metal film 23.

The lower insulating film 18, the lower metal film 17, and the light blocking portion 16 are provided. The lower insulating film 18 is disposed in the layer lower than the semiconductor film 19. The lower metal film 17 is disposed in the layer lower than the lower insulating film 18. The light blocking portion 16 is prepared from the lower metal film 17 and disposed to overlap at least the channel regions 11D. Even if light is applied to the semiconductor film 19 from the lower layer side, light rays traveling toward the channel regions 11D are blocked by the light blocking portion 16 that are formed from the lower metal film 17 and disposed to overlap at least the channel regions 11D. The lower metal film 17 is disposed in the layer lower than the semiconductor film 19 via the lower insulating film 18. According to the configuration, variations in characteristics of the TFTs 11, which may occur when the light is applied to the channel regions 11D, are less likely to occur.

The gate lines 13 formed from the first metal film 21 and coupled to the gate electrodes 11A are provided. According to the configuration, the signals transmitting through the gate lines 13 are supplied to the gate electrodes 11A. In comparison to a configuration in which gate lines are portions of a metal film disposed in a layer lower than the first metal film 21, the structure for connecting the gate lines 13 to the gate electrodes 11A are portions of the first metal film 21 can be simplified.

The second insulating film 22 is disposed to cover at least the drain regions 11C and the pixel electrodes 12. According to the configuration, at least the drain regions 11C and the pixel electrodes 12 are covered with the second insulating film 22 during the etching of the second metal film 23 formed in the layer upper than the second insulating film 22 to form the source lines 14 in the production process. Even if the etching of the second metal film 23 is not properly performed and film residues are present, defects such as short-circuits between the source liens 14 and at least one of the drain regions 11C and the pixel electrodes 12 are less likely to occur due to the film residues. Because at least the drain regions 11C and the pixel electrodes 12 are covered with the second insulating film 22, at least the drain regions 11C and the pixel electrodes 12 are less likely to be over-etched during the etching of the second metal film 23.

The first insulating film 20 is disposed in the area overlapping the first metal film 21. According to the configuration, the first insulating film 20 can be etched together with the first metal film 21 that is etched after the first insulating film 20 and the first metal film 21 are formed in sequence. Namely, a photomask for patterning the first insulating film 20 is not required and thus the production cost can be reduced. With the first insulating film 20 overlapping the gate electrodes 11A that are the portions of the first metal film 21, the distances between the gate electrodes 11A and the channel regions 11D are maintained constant.

The semiconductor film 19 is prepared from the oxide semiconductor. In comparison to amorphous silicon, the oxide semiconductor has a larger band gap in general. Because the semiconductor film 19 is an oxide semiconductor film 19, ability of the TFTs 11 to withstand high voltages is improved.

The method of producing the array substrate 10 according to this embodiment includes the semiconductor film forming step, the first insulating film forming step, the first metal film forming step, the first metal film etching step, the semiconductor film etching step, the resistance reducing step, the second insulating film forming step, the second insulating film etching step, the second metal film forming step, and the second metal film etching step. The semiconductor film forming step is for forming the semiconductor film 19. The first insulating film forming step is for forming the first insulating film 20 in the layer upper than the semiconductor film 19. The first metal film forming step is for forming the first metal film 21 in the layer upper than the first insulating film 20. The first metal film etching step is for etching the first metal film 21 together with the first insulating film 20 to form the gate electrodes 11A of the TFTs from the first metal film 21. The semiconductor film etching step is for etching the semiconductor film 19. The resistance reducing step is for reducing the resistances of the sections of the semiconductor film 19 other than the channel regions 11D overlapping the gate electrodes 11A to form the source regions 11B of the TFTs 11, the drain regions 11C of the TFTs 11, and the pixel electrodes 12 so that the source regions 11B are coupled to the channel regions 11D, the drain regions 11C are coupled to the channel regions 11D from the opposite side from the source regions 11B, and the pixel electrodes 12 are coupled to the drain regions 11C. The second insulating film forming step is for forming the second insulating film 22 in the layer upper than the first metal film 21. The second insulating film etching step is for etching the second insulating film 22 to form the contact holes 26 in the sections of the second insulating film 22 overlapping sections of the source regions 11B. The second metal film forming step is for forming the second metal film 23 in the layer upper than the second insulating film 22. The second metal film etching step is for etching the second metal film 23 to form the source lines 14 connected to the source regions 11B via the contact holes 26.

The semiconductor film 19, the first insulating film 20, and the first metal film 21 are formed through the semiconductor film forming step, the first insulating film forming step, and the first metal film forming step. In the first metal film etching step, the first metal film 21 is etched together with the first insulating film 20. In the semiconductor film etching step, the semiconductor film 19 is etched. In the resistance reducing step, the resistances of the sections of the semiconductor film 19 other than the channel regions 11D are reduced and the source regions 11B, the drain regions 11C, and the pixel electrodes 12 are formed. According to the method, the forming and the etching of the transparent electrode film are not required. Furthermore, insulating films for isolating the transparent electrode film from other conductive films are not required. In comparison to a method including forming the pixel electrodes from the transparent electrode film, this method is preferable for reducing the production cost. The second insulating film 22 formed in the second insulating film forming step is etched in the second insulating film etching step and the contact holes 26 are formed in the sections of the second insulating film 22 overlapping the sections of the source regions 11B. The second metal film 23 formed in the layer upper than the second insulating film 22 in the second metal film forming step is etched in the second metal film etching step and the source lines 14 connected to the source regions 11B via the contact holes 26 are formed. In the second metal film etching step, at least the sections of the semiconductor film 19 are covered with the second insulating film 22. Even if the second metal film 23 is not properly etched and film residues are present, defects such as short-circuits between the source lines 14 and the sections of the semiconductor film 19 prepared by reducing the resistances are less likely to occur due to the film residues. Because at least the sections of the semiconductor film 19 are covered with the second insulating film 22, the semiconductor film 19 is less likely to be over-etched in the second metal film etching step.

The first metal film etching step is performed prior to the semiconductor film etching step. When the first metal film 21 is etched together with the first insulating film 20 in the first metal film etching step, the semiconductor film 19 is not patterned and the layer under the semiconductor film 19 is covered with the semiconductor film 19. Therefore, the layer under the semiconductor film 19 is less likely to be over-etched during the etching of the first metal film 21.

### Second Embodiment

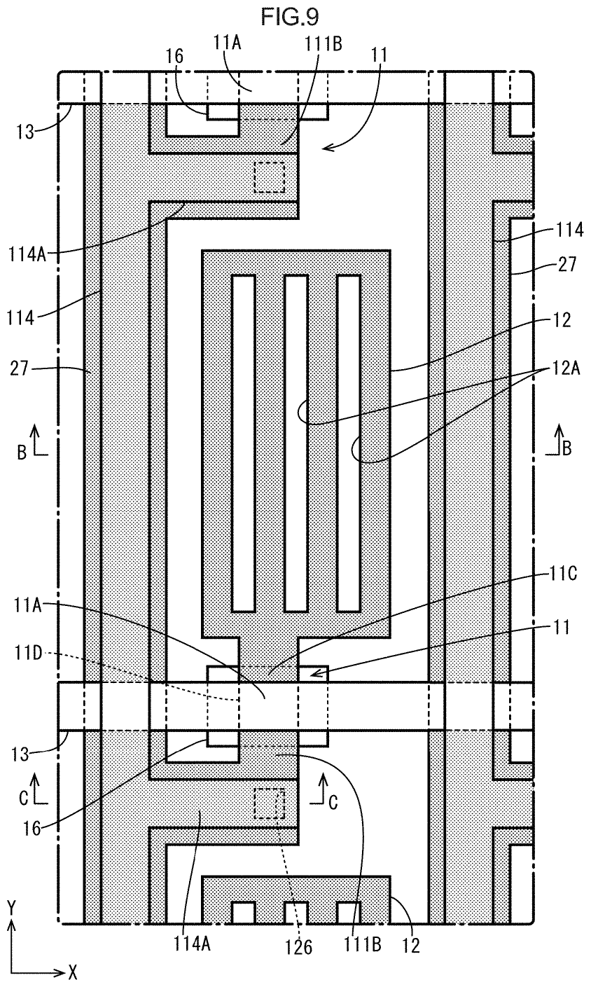

A second embodiment will be described with reference to FIGS. 9 to 11. The second embodiment includes auxiliary source lines 27 prepared by reducing resistances of sections of a semiconductor film 119. Configurations, functions, and effects similar to those of the first embodiment will not be described.

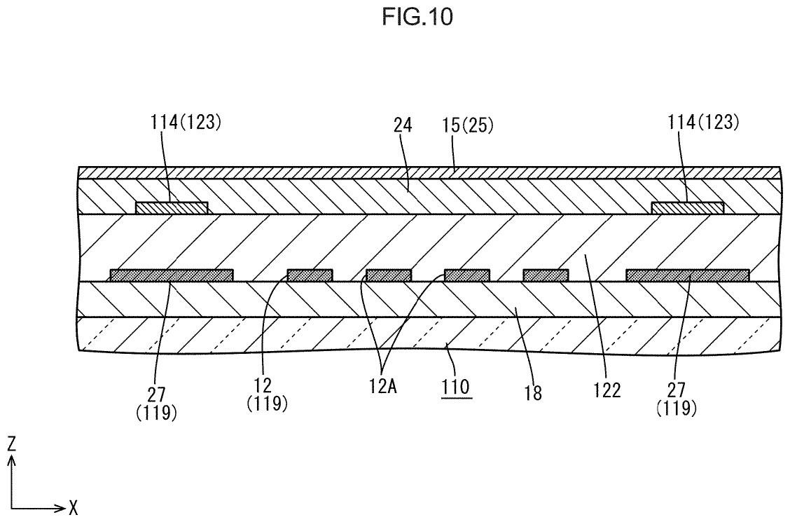

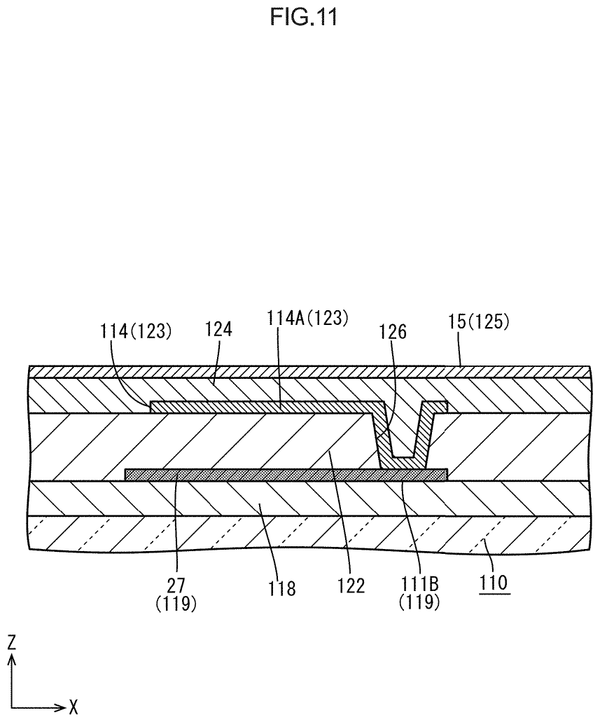

As illustrated in FIGS. 9 and 10, an array substrate 110 according to this embodiment includes the auxiliary source lines 27 that are prepared by reducing the resistances of the sections of the semiconductor film 119. The auxiliary source lines 27 extend parallel to source lines 114 and source branch lines 114A. Sections of the auxiliary source lines 27 with respect to a width direction overlap the source lines 114 and the source branch lines 114A for entire lengths. The auxiliary source lines 27 are wider than the source lines 114 and the source branch lines 114A. Ends of the source lines 114 and the source branch lines 114A in the width direction do not overlap the source lines 114 and the source branch lines 114A. Namely, the source lines 114 and the source branch lines 114A are narrower than the auxiliary source lines 27. As illustrated in FIG. 11, the auxiliary source lines 27 include ends that are coupled to source regions 111B. The source branch lines 114A are connected to the source regions 111B via contact holes 126. Therefore, the auxiliary source lines 27 are electrically connected to the source lines 114 and thus able to transmit signals to be transmitted by the source lines 114. Namely, the source lines 114 are double-track lines. Even if the source lines 114 are broken, the signals can be transmitted by the auxiliary source lines 27 or the broken source lines 114 may be repair using the auxiliary source lines 27. Furthermore, line resistances of the source lines 114 are reduced.

As described above, this embodiment includes the auxiliary source lines 27 that are prepared by reducing the resistances of the sections of the semiconductor film 119, coupled to the source regions 111B, and disposed to overlap at least the sections of the source lines 114. Because the source lines 114 are connected to the auxiliary source lines 27 via the source regions 111B, redundancy is improved and line resistance are reduced.

The source lines 114 are narrower than the auxiliary source lines 27. Because the line resistances of the source lines 114 are reduced by the auxiliary source lines 27, the line resistances are sufficiently low although the source lines 114 are narrower than the auxiliary source lines 27. In general, the source lines 114 prepared from a second metal film 123 tend to have sheet resistances lower than those of the auxiliary source lines 27 that are prepared by reducing the resistances of the sections of the semiconductor film 119. Loads on the source lines 114 tend to be affected by parasitic capacitances between the source lines 114 and other lines more than parasitic capacitances between the auxiliary source lines 27 and other lines. Based on the above tendency, the parasitic capacitances between the source lines 114 and other lines are properly reduced with the source lines 114 narrower than the auxiliary source lines 27. Namely, this is preferable for reducing the loads on the source lines 114.

### Third Embodiment

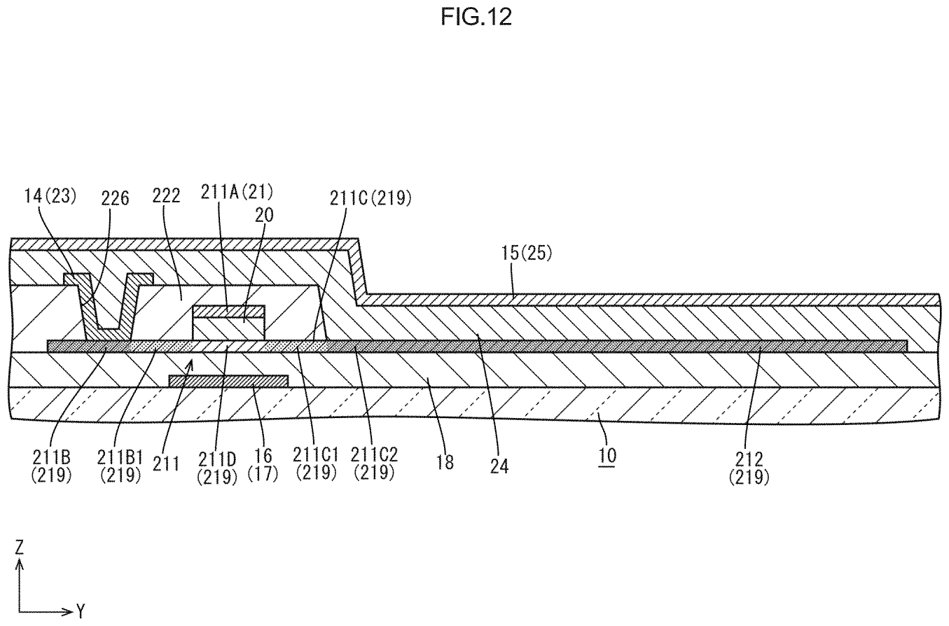

A third embodiment will be described with reference to FIGS. 12 to 14. The third embodiment includes a second insulating film 222, a material and a structure of which are different from the first embodiment. Configurations, functions, and effects similar to those of the first embodiment will not be described.

As illustrated in FIG. 12, an array substrate 210 according to this embodiment includes the second insulating film 222 made of SiO₂, which is one kind of silicon oxide. Oxygen is contained in the second insulating film 222. The second insulating film 222 is formed to overlap at least channel adjoining sections 211B1 of source regions 211B and channel adjoining sections 221C1 of drain regions 211C prepared from a semiconductor film 219 and adjacent to channel regions 211D. The second insulating film 222 overlaps sections of the source regions 211B on an opposite side from a channel adjoining section 211B1 side relative to contact holes 226. The second insulating film 222 is formed not to overlap pixel adjoining sections 211C2 and pixel electrodes 212. The pixel adjoining sections 211C2 are sections of the drain regions 211C prepared from the semiconductor film 219 adjacent to the pixel electrodes 212. The pixel electrodes 212 are portions of the semiconductor film 219. Resistances of sections of the semiconductor film 219 overlapping the second insulating film 222 increase as the oxygen contained in the second insulating film 222 is introduced over time. Therefore, the channel adjoining sections 211B1 and 211C1 overlapping the second insulating film 222 are high resistance regions. The oxygen contained in the second insulating film 222 is not introduced to sections of the semiconductor film 219 not overlapping the second insulating film 222. Therefore, the pixel adjoining sections 211C2 and the pixel electrodes 212 not overlapping the second insulating film are low resistance regions having resistances lower than those of the high resistance regions. The high resistance regions and the low resistance regions are resistance-reduced regions prepared by reducing the resistances. In FIG. 12, the low resistance regions of the semiconductor film 219 are shaded deeper and the high resistance regions of the semiconductor film 219 are shaded lighter.

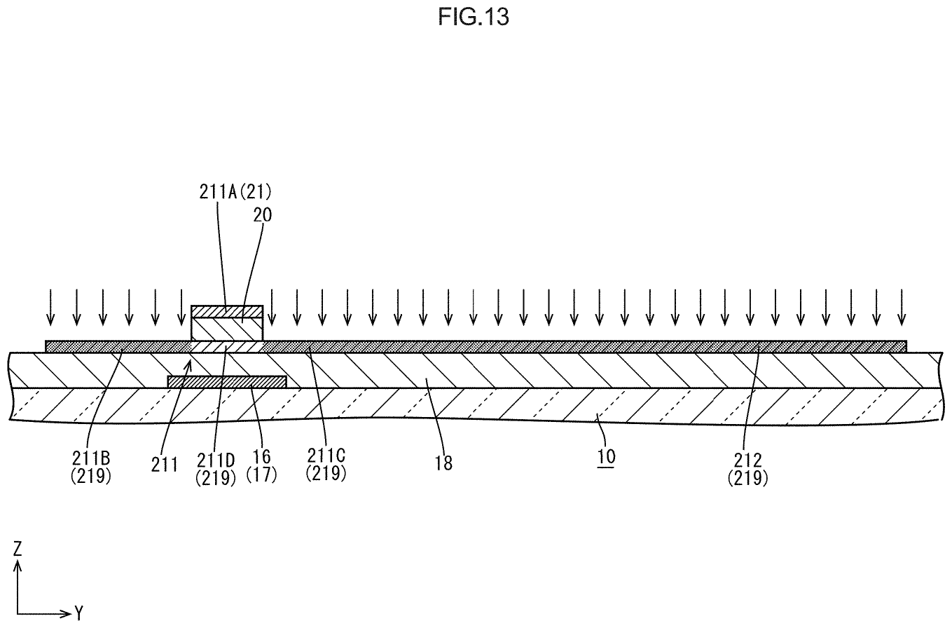

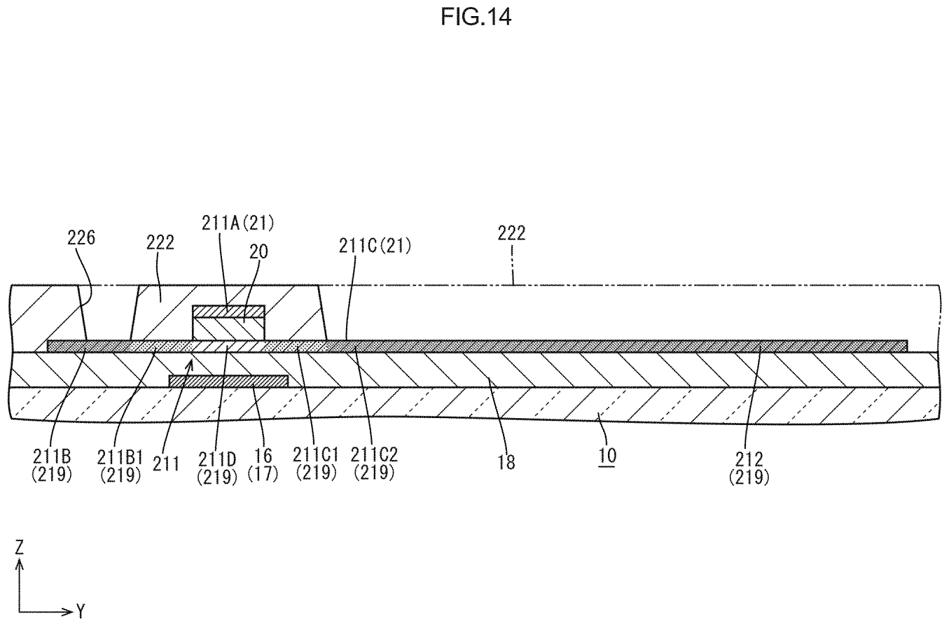

A method of producing the array substrate 210 will be described. When the lower metal film forming step, the lower metal film etching step, the lower insulating film forming step, the semiconductor film forming step, the first insulating film forming step, the first metal forming step, the first metal film etching step, the semiconductor film etching step, and the resistance reducing step are complete, the resistances of the source regions 211B, the drain regions 211C, and the pixel electrodes 212 of the semiconductor film 219 other than the channel regions 211D are reduced as illustrated in FIG. 13. In this stage, the resistances of the source regions 211B, the drain regions 211C, and the pixel electrodes 212 are about equal. The second insulating film 222 formed in the second insulating film forming step is etched in the second insulating film etching step as illustrated in FIG. 14. In this step, contact holes 226 are formed in the second insulating film 222 at positions overlapping sections of the source regions 211B. Furthermore, sections of the second insulating film 222 overlapping the pixel adjoining sections 211C2 of the drain regions 211C adjacent to the pixel electrodes 212 and the pixel electrodes 212 are removed. The sections of the source regions 211B overlapping the contact holes 26, the pixel adjoining sections 211C2 of the drain regions 211C, and the pixel electrodes 212 of the semiconductor film 219 are exposed without covered with the second insulating film 222 and the low resistance regions. The channel adjoining sections 211B1 and the sections on the opposite side of the source regions 211B and the channel adjoining sections 211C1 of the drain regions 211C of the semiconductor film 219 are covered with the second insulating film 222. Therefore, the oxygen contained in the second insulating film 222 is introduced to those sections over time and thus those sections become high resistance sections.

According to this embodiment, the second insulating film 222 contains at least the silicon oxide and overlaps the sections of the source regions 211B and the drain regions 211C adjacent to the channel regions 211D but not the sections of the drain regions 211C adjacent to the pixel electrodes 212 and the pixel electrodes 212. The second insulating film 222 contains at least the silicon oxide and thus contains oxygen. At least the sections of the source regions 211B and the drain regions 211C adjacent to the channel regions 211D overlap the second insulating film 222. Therefore, the oxygen contained in the second insulating film is introduced over time and thus the resistances increase. The sections of the source regions 211B overlapping the contact holes 226, the sections of the drain regions 211C adjacent to the pixel electrodes 212, and the pixel electrodes 212 do not overlap the second insulating film 222. Therefore, the oxygen contained in the second insulating film 222 is not introduced. The resistances of the source regions 211B and the drain regions 211C are low on the opposite side from the channel regions 211D but high on the channel side. The electric fields between the source regions 211B and the drain regions 211C are compensated. Therefore, electric field concentration (so-called hot-carrier phenomenon) is less likely to occur around the drain regions 211C and thus off-state leakage currents in TFTs 211 can be reduced.

### Fourth Embodiment

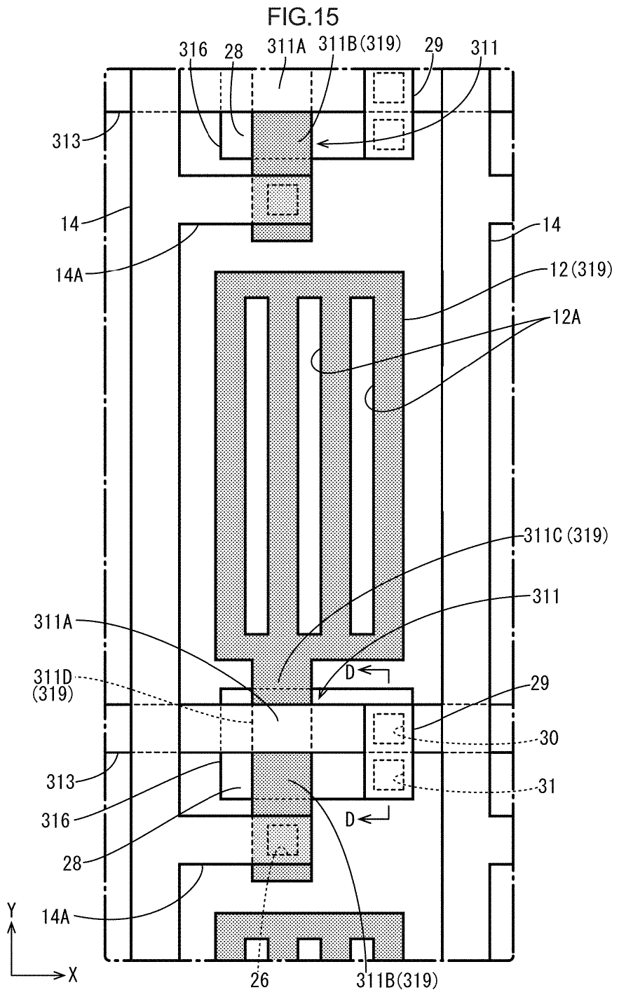

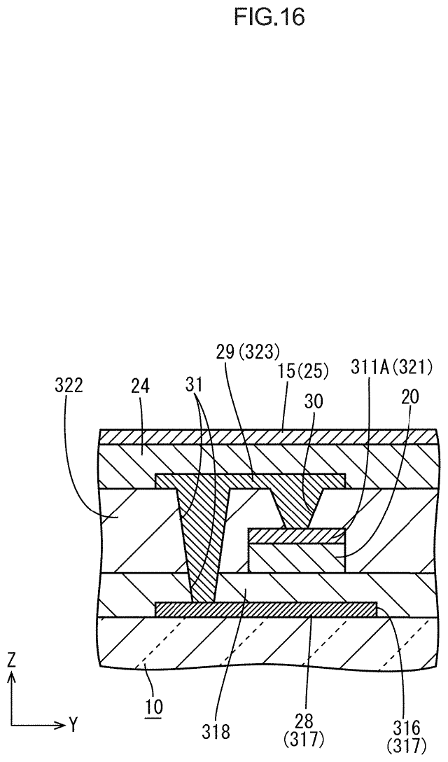

A fourth embodiment will be described with reference to FIGS. 15 and 16. The fourth embodiment includes TFTs 311 having a configuration different from that of the first embodiment. Configurations, functions, and effects similar to those of the first embodiment will not be described.

As illustrated in FIGS. 15 and 16, the TFTs 311 according to this embodiment include lower gate electrodes 28, that is, have a double-gate configuration. The lower gate electrodes 28 are included in a light blocking portion 316 that is a portion of a lower metal film 317 and disposed to overlap gate electrodes 311A and channel regions 311D. The lower gate electrodes 28 (the light blocking portion 316) are connected to the gate electrodes 311A prepared from a first metal film 321 via inter-electrode connecting portions 29. The inter-electrode connecting portions 29 are portions of a second metal film 323. The inter-electrode connecting portions 29 overlap the lower gate electrodes 28 and the gate electrodes 311A but not source regions 311B, drain regions 311C, and the channel regions 311D that are portions of a semiconductor film 319. First inter-electrode contact holes 30 are formed in sections of a second insulating film 322 overlapping the inter-electrode connecting portions 29 and the gate electrodes 311A. Second inter-electrode contact holes 31 are formed in sections of the second insulating film 322 and the lower insulating film 319 overlapping the inter-electrode connecting portions 29 and the lower gate electrodes 28. The inter-electrode connecting portions 29 are electrically connected to the gate electrodes 311A and the lower gate electrodes 28 via the first inter-electrode contact holes 30 and the second inter-electrode contact holes 31. According to the configuration, signals transmitting through gate lines 313 that are portions of the first metal film 321 are supplied to the gate electrodes 311A and the lower gate electrodes 28 at the same time. Therefore, an amount of electric charges flowing through the channel regions 311D that overlap the gate electrodes 311A and the lower gate electrodes 28 increases.

According to this embodiment, as described above, the light blocking portion 316 includes the lower gate electrodes 28. With the signals supplied to not only the gate electrodes 311A but also the lower gate electrodes 28, the amount of electric charges flowing through the channel regions 311D that overlap the lower gate electrodes 28 can be increased.

### Fifth Embodiment

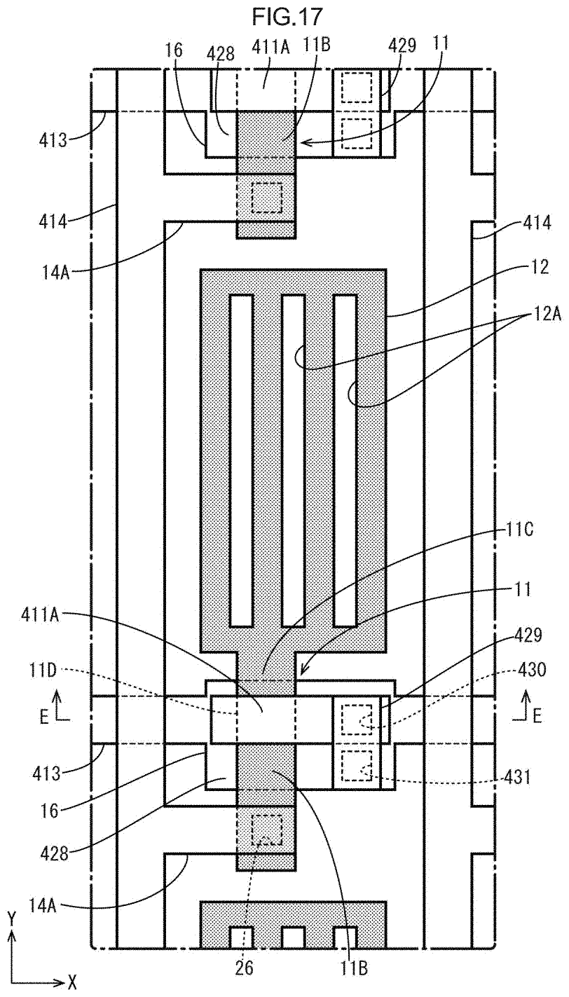

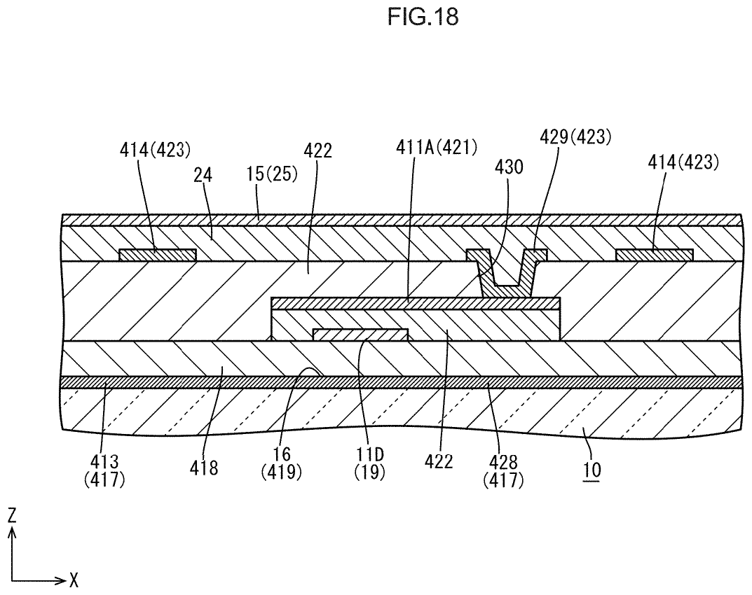

A fifth embodiment will be described with reference to FIGS. 17 and 18. The fifth embodiment includes gate lines 413 having a configuration different from those of the fourth embodiment. Configurations, functions, and effects similar to those of the first embodiment will not be described.

As illustrated in FIGS. 17 and 18, the gate lines 413 according to this embodiment are portions of a lower metal film 417 and coupled to gate electrodes 428. Gate electrodes 411A that are portions of a first metal film 421 are connected to the lower gate electrodes 428 via inter-electrode connecting portions 429 to supply signal transmitting through the gate lines 413 thereto. A configuration for connecting inter-electrode connecting portions 429 to the gate electrodes 411A and the lower gate electrodes 428 is similar to that of the fourth embodiment. First inter-electrode contact holes 430 in second insulating film 422 and second inter-electrode contact holes 431 in lower insulating film 418 are used. In this embodiment, the gate lines 413 are the portions of the lower metal film 417. Therefore, as illustrated in FIG. 18, the lower insulating film 418 and the second insulating film 422 are present between the gate lines 413 and source lines 414 at intersections between the gate lines 413 and the source lines 414. In comparison to the configuration in which the gate lines prepared from the first metal film 421 and only the second insulating film 422 is present between the gate lines and the source lines 414 at intersections between the gate lines and the source lines 414, distances between the gate lines 413 and the source lines 414 at the intersections are larger. Therefore, loads on the source are reduced and thus rounding of the signals transmitting through the source lines 414 is less likely to occur. This configuration is preferable for providing high definition.

As described above, this embodiment includes the inter-electrode connecting portions 429 and the gate lines 413. The inter-electrode connecting portions 429 are portions of a second metal film 423 and connected to the gate electrodes 411A and the lower gate electrodes 428 via the first inter-electrode contact holes 430 in the second insulating film 422 and the second inter-electrode contact holes 431 at least in the lower insulating film 418 and the second insulating film 422. The gate lines 413 are portions of the lower metal film 417 and coupled to the lower gate electrodes 428. The signals transmitting through the gate lines 413 are supplied to the lower gate electrodes 428 coupled to the gate lines 413 and from the lower gate electrodes 428 to the gate electrodes 411A via the inter-electrode connecting portions 429. According to the configuration, the signals are supplied to the lower gate electrodes 428 and the gate electrodes 411A at the same time. Because the gate lines 413 are prepared from the lower metal film 417, at least the lower insulating film 418 and the second insulating film 422 are present between the gate lines 413 and the source lines 414 at the intersections between the gate lines 413 and the source lines 414. In comparison to the configuration in which the gate lines are prepared from the first metal film 421 and only the second insulating film 422 is present between the gate lines and the source lines 414 at the intersections between the gate lines and the source lines 414, the distances between the gate lines 413 and the source lines 414 at the intersections are larger. Therefore, the loads on the source lines 414 are reduced and rounding of the signals transmitting through the source lines 414 is less likely to occur. This configuration is preferable for providing high definition.

### Other Embodiments

The technology described herein is not limited to the embodiments described in the above descriptions and drawings. The following embodiments may be included in the technical scope of the technology described herein.

(1) In each of the above embodiments, the plasma processing is used for reducing the resistances in the resistance reducing step. However, vacuum annealing may be used for reducing the resistances.

(2) In the second embodiment, the source lines and the source branch lines are narrower than the auxiliary source lines. However, the source lines and the source branch lines may have widths about equal to that of the auxiliary source lines. The source lines and the source branch lines may be narrower than the auxiliary source lines. The source lines may have a width different from that of the source branch lines. In this configuration, a relation in width between the auxiliary source lines and the source lines may be different from a relation in width between the auxiliary source lines and the source branch lines.

(3) In the third embodiment, SiO₂ is used for the silicon oxide in the second insulating film. Other types of silicon oxide such as silicon oxynitride (SiNO) may be used for the silicon oxide in the second insulating film.

(4) In each of the fourth and the fifth embodiments, only one gate line is connected to each TFT having the double-gate configuration. However, two gate lines may be connected to each TFT having the double-gate configuration. Namely, one of two gate lines that are electrically independent from each other may be connected to the gate electrode and the other gate line may be connected to the lower gate electrode. According to the configuration, the signals can be supplied to the gate electrode and the lower gate electrode with different timings.

(5) In each of the above embodiments, the sections of the gate lines are defined as the gate electrodes or the lower gate electrodes and the source branch lines branched off from the source lines are connected to the source regions. However, the source branch lines may not be provided, sections of the source lines may be connected to the source regions, and gate branch portions branched off from the gate lines may be defined as gate electrodes.

(6) The number and the shape of the slits formed in the pixel electrodes may be altered from those of each of the above embodiments. The outline of each pixel electrode may be altered to a shape other than the simple rectangular shape where appropriate.

(7) In each of the above embodiments, the light blocking portion (the lower gate electrodes) is prepared from the lower metal film. However, the light blocking portion may be omitted. In such a configuration, the lower metal film and the lower insulating film may be omitted.

(8) Each of the above embodiments includes the array substrate that includes the oxide semiconductor film as a semiconductor film. However, continuous grain silicon (CG silicon) which is one kind of polysilicon (polycrystalline silicon) or amorphous silicon may be used for a material of the semiconductor film.

(9) The materials of the metal films and the insulating films may be altered from those in each of the above embodiments.

(10) Each of the above embodiments includes the array substrate for the liquid crystal panel configured to operate in FFS mode. However, the technology described herein can be applied to array substrates for liquid crystal panels configured to operate in in-plane switching (IPS) mode, vertical alignment (VA) mode, and other modes.

(11) Each of the above embodiments includes the array substrate for the liquid crystal panel. However, the technology described herein can be applied to array substrates for other types of display panels (organic EL panels, plasma display panels (PDPs), microcapsule-type electrophoretic display panels (EPDs), micro electro mechanical systems (MEMS) display panels).

1. A thin film transistor substrate comprising:
a semiconductor film;
a first insulating film disposed in a layer upper than the semiconductor film;
a first metal film disposed in a layer upper than the first insulating film;
a second insulating film in a layer upper than the first metal film;
a second metal film in a layer upper than the second insulating film;
a source line that is a portion of the second metal film;
a gate electrode that is a portion of the first metal film and included in the thin film transistor;
a channel region that is a portion of a section of the semiconductor film, disposed to overlap the gate electrode, and included in the thin film transistor;
a source region prepared by reducing a resistance of a section of the semiconductor film, coupled to the channel region, connected to the source line via a contact hole formed in the second insulating film, and included in the thin film transistor;
a drain region prepared by reducing a resistance of a section of the semiconductor film, coupled to the channel region on an opposite side from the source region, and included in the thin film transistor; and
a pixel electrode prepared by reducing a resistance of a section of the semiconductor film and coupled to the drain region.

2. The thin film transistor substrate according to claim 1, further comprising:
a lower insulating film disposed in a layer lower than the semiconductor film;
a lower metal film disposed in a layer lower than the lower insulating film; and
a light blocking portion that is a portion of the lower insulating film and disposed overlap at least the channel region.

3. The thin film transistor substrate according to claim 2, wherein the light blocking portion includes a lower gate electrode.

4. The thin film transistor substrate according to claim 3, further comprising:
an inter-electrode connecting portion that is a portion of the second metal film and connected to the gate electrode and the lower gate electrode via a first inter-electrode contact hole formed in the second insulating film and via second inter-electrode contact holes formed in at least the lower insulating film and the second insulating film; and
a gate line that is a portion of the lower metal film and coupled to the lower gate electrode.

5. The thin film transistor substrate according to claim 1, further comprising a gate line that is a portion of the first metal film and coupled to the gate electrode.

6. The thin film transistor substrate according to claim 1, further comprising an auxiliary source line prepared by reducing a resistance of a section of the semiconductor film, coupled to the source region, and disposed such that at least a section thereof overlaps the source line.

7. The thin film transistor substrate according to claim 6, wherein the source line is narrower than the auxiliary source line.

8. The thin film transistor substrate according to claim 1, wherein the second insulating film is disposed cover at least the drain region and the pixel electrode.

9. The thin film transistor substrate according to claim 1, wherein the second insulating film is formed to contain at least silicon oxide and to overlap at least sections of the source region and the drain region adjacent to the channel region but not a section of the drain region adjacent to the pixel electrode and the pixel electrode.

10. The thin film transistor substrate according to claim 1, wherein the first insulating film is disposed in an area overlapping the first metal film.

11. The thin film transistor substrate according to claim 1, wherein the semiconductor film is an oxide semiconductor film.

12. A method of producing a thin film transistor substrate, the method comprising:
a semiconductor film forming step of forming a semiconductor film;
a first insulating film forming step of forming a first insulating film in a layer upper than the semiconductor film;
a first metal film forming step of forming a first metal film in a layer upper than the first insulating film;
a first metal film etching step of etching the first metal film and the first insulating film together to prepare a gate electrode from the first metal film, the gate electrode being included in a thin film transistor;
a semiconductor film etching step of etching the semiconductor film;
a resistance reducing step of reducing resistance of sections of the semiconductor film other than a channel region overlapping the gate electrode to prepare a source region coupled to the channel region and included in the thin film transistor, a drain region coupled to the channel region on an opposite side from the source region and included in the thin film transistor, and a pixel electrode coupled to the drain region;
a second insulating film forming step of forming a second insulating film in a layer upper than the first metal film;
a second insulating film etching step of etching the second insulating film to form a contact hole in a section overlapping a section of the source region;
a second metal film forming step of forming a second metal film in a layer upper than the second insulating film; and
a second metal film etching step of etching the second metal film to prepare a source line connected to the source region via the contact hole.

13. The method of producing the thin film transistor substrate according to claim 12, wherein the first metal film etching step is performed prior to the semiconductor film etching step.
